(19) United States
(12) Patent Application Publication
(10) Pub. No.: US 2014/0190550 A1
(43) Pub. Date: Jul. 10, 2014

(54) TANDEM SOLAR CELL WITH GRAPHENE INTERLAYER AND METHOD OF MAKING

(71) Applicants: Kian Ping Loh, Kent Ridge (SG); Shi Wun Tong, Kent Ridge (SG); Yu Wang, Kent Ridge (SG)

(72) Inventors: Kian Ping Loh, Kent Ridge (SG); Shi Wun Tong, Kent Ridge (SG); Yu Wang, Kent Ridge (SG)

(73) Assignee: NATIONAL UNIVERSITY OF SINGAPORE, Kent Ridge (SG)

(21) Appl. No.: 14/238,305

(22) PCT Filed: Aug. 8, 2012
(86) PCT No.: PCT/SG2012/000281

§ 371 Date: Feb. 11, 2014

Related U.S. Application Data
(60) Provisional application No. 61/522,325, filed on Aug. 11, 2011.

(51) Int. Cl. H01L 51/44

(52) U.S. Cl. CPC H01L 51/445
USPC 136/244

(57) ABSTRACT

A tandem solar cell with graphene interlayer and method of making are disclosed. The graphene interlayer can serve as a recombination contact to a pair of photoactive subcells electrically connected in series or as a common electrode to a pair of photoactive subcells electrically connected in parallel. The highly conducting, transparent nature, and easily modifiable chemical and electrical properties of a graphene interlayer enable tunable energy matching to the photoactive subcells. Using different photoactive subcells that can harvest light across the solar spectrum results in a tandem solar cell that can achieve high power conversion efficiency.

### CROSS REFERENCE TO RELATED APPLICATIONS

This application claims the benefit of U.S. Provisional Application Ser. No. 61/522,325 filed on 11 Aug. 2011 and entitled “Graphene as Intermediate Layer in Tandem Solar Cell”, which is incorporated by reference herein in its entirety.

### FIELD OF INVENTION

The present invention relates generally to solar cells, and more particularly, to a tandem solar cell having graphene as an interlayer in either a series or a parallel connection with photoactive subcells that form the solar cell and a method for manufacturing the tandem solar cell.

### BACKGROUND

A solar cell is a device that converts photons from sunlight directly into electricity using the photovoltaic effect. Solar cells based on organic materials and polymers have attracted broad research interest and are considered as promising alternatives to their inorganic counterparts. Among their attractive features, solar cells based on organic materials and polymers are low-cost, flexible, have low-energy consumption, incorporate high-throughput processing technologies, are aesthetically pleasing, and are versatile for many applications.

Polymer or fullerene based bulk-heterojunction (BHJ) polymer solar cells is one type of solar cell based on organic material and polymers. The BHJ polymer solar cells typically have solar cell efficiencies that can range from 5% to 10%, however, the efficiency of this type of polymer solar cell is still low compared to inorganic solar cells. One of the efficiency-limiting aspects of polymer solar cells such as a BHJ polymer solar cell is their normally high optical bandgap which leads to inefficient absorption of solar irradiation.

Tandem solar cells made of two or more single photoactive cells (photoactive subcells) in series or parallel can boost the efficiency to more than 15%, compared to the 10% limit of single BHJ solar cell devices. Nevertheless, producing a tandem cell is not an easy task, largely due to the thinness of the materials and the difficulties in extracting the current between the layers.

One method of constructing a tandem solar cell, as disclosed by V. Shrotriya et al., Appl. Phys. Lett. 88, 064104 (2006), includes mechanically stacking two identical photoactive subcells onto different glass substrates and then positioning them on top of each other. The solar efficiency of such a tandem solar cell is double the efficiency of each of the two individual photoactive subcells, however, implementing this method in a manufacturing process is complex.

Another method of constructing a tandem solar cell includes inserting an intermediate layer, between the two active layers of each photoactive subcell. The intermediate layer provides electrical contact between the two photoactive subcells via efficient recombination or charge collection without voltage loss. The intermediate layer can be made from a variety of materials. For example, K. Kawano et al., Appl. Phys. Lett., 88, 073514 (2006), and J. Sakai et al., Solar Energy Materials & Solar Cells 94, 376 (2010) disclosed the use of transparent conductive oxides such as indium tin oxide (ITO). In other instances, conductive metallic thin films have been used as the intermediate layer because they generally have a low transparency (less than 60% at 550 nm) that can reduce the light transfer to the solar cells dramatically. For example, S. Sista et al., Adv. Mater. 22, E77 (2010) disclosed using gold (Au) as an intermediate layer, while X. Y. Guo et al., Organic Electronics 10, 1174 (2009) disclosed using aluminum silver (Al/Ag) as the intermediate layer. However, use of such materials has been less than ideal. As an example, for tandem solar cells that use an intermediate layer formed from ITO, a magnetron sputtering process is typically used to deposit the ITO. However, the magnetron sputtering process is too energetic and can easily damage the underlying solar sub-cells.

### SUMMARY

In one embodiment, a tandem organic photovoltaic cell is disclosed. In this embodiment, the tandem organic photovoltaic cell comprises: a first photoactive subcell; a second photoactive subcell; and an intermediate layer comprising graphene, disposed between the first photoactive subcell and the second photoactive subcell, that collects charges generated from the first photoactive subcell and the second photoactive subcell.

In a second embodiment a tandem photovoltaic cell is disclosed. In this embodiment, the tandem photovoltaic cell comprises: two or more photoactive subcells; a graphene film layer disposed between each pair of photoactive subcells in the two or more photoactive subcells. The graphene film layer provides an electrical connection between each pair of photoactive subcells, wherein the graphene film layer provides a selective contact of a same polarity to each pair of photoactive subcells to collect charges generated therefrom.

In a third embodiment, a tandem optoelectronic device is disclosed. In this embodiment, the optoelectronic device comprises: two or more optoelectronic active subcells; and a graphene film layer is disposed between each pair of optoelectronic active subcells in the two or more optoelectronic active subcells. The graphene film layer provides an electrical connection between each pair of optoelectronic active subcells, wherein the graphene film layer provides a selective contact of a same polarity to each pair of optoelectronic active subcells to collect charges generated therefrom.

In a fourth embodiment, a method of fabricating a tandem organic photovoltaic cell is disclosed. In this embodiment, this method comprises: obtaining a graphene film layer; disposing the graphene film layer as an intermediate layer between two or more organic photoactive subcells; and electrically connecting the two or more organic photoactive subcells through the graphene film layer to collect charges generated from the two or more organic photoactive subcells.

### BRIEF DESCRIPTION OF THE DRAWINGS

FIG. 1 is a schematic diagram of a series tandem photovoltaic cell in which a graphene intermediate layer is interposed between two photoactive subcells according to one embodiment of the present invention;

FIG. 2 is a schematic diagram of a series tandem photovoltaic cell according to another embodiment of the present invention;

FIG. 3 is a schematic diagram of a parallel tandem photovoltaic cell in which a graphene intermediate layer is interposed between two photoactive subcells according to one embodiment of the present invention;

FIG. 4 is a schematic diagram of a parallel tandem photovoltaic cell according to another embodiment of the present invention;

FIG. 5 is a flow chart describing a method for fabricating a tandem photovoltaic cell such as the ones depicted in FIGS. 1-4 according to one embodiment of the present invention;

FIG. 6 is a graph that shows the photocurrent density as a function of the voltage under illumination of 100 mW/cm² for a tandem photovoltaic cell like the ones depicted in FIGS. 1-2; and

FIG. 7 is a graph that shows the photocurrent density as a function of the voltage under illumination of 100 mW/cm² for a tandem photovoltaic cell like the ones depicted in FIGS. 3-4.

### DETAILED DESCRIPTION OF THE EMBODIMENTS

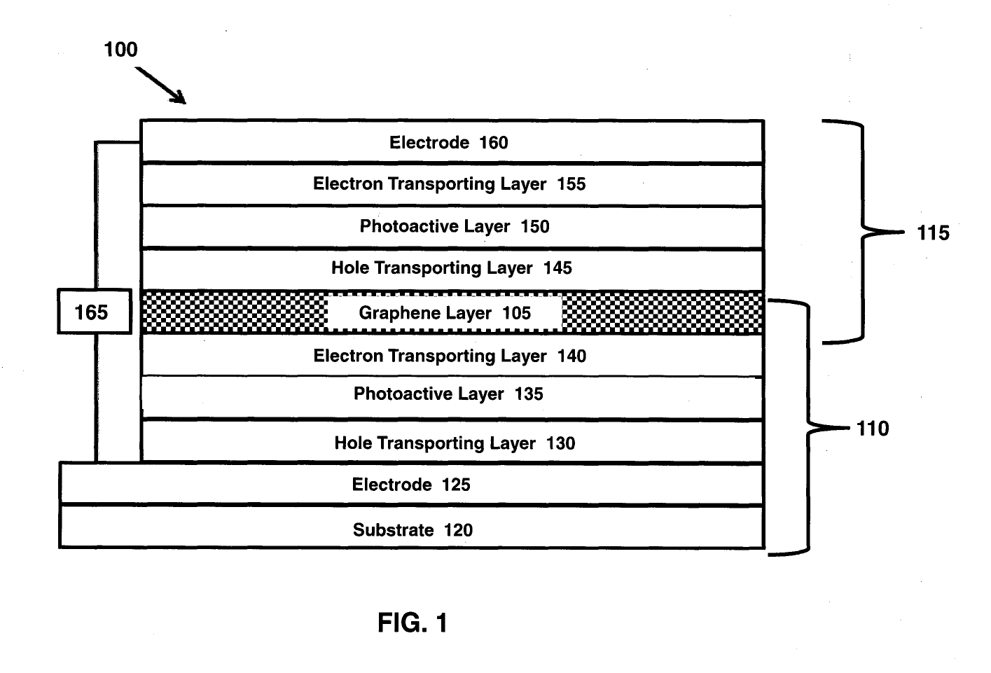

FIG. 1 is a schematic diagram of a tandem solar cell also referred to herein as a tandem photovoltaic cell according to one embodiment of the present invention. In particular, FIG. 1 shows a series tandem photovoltaic cell 100 in which a graphene intermediate layer 105 is interposed between two photoactive subcells 110 and 115. In one embodiment, the graphene intermediate layer 105 provides an electrical connection between the photoactive subcell 110 and the photoactive subcell 115. As shown in FIG. 1, the photoactive subcell 110 and the photoactive subcell 115 are electrically coupled in series. The photoactive subcell 110 comprises a substrate 120, an electrode 125 disposed on the substrate 120, a hole transporting layer 130 disposed on the electrode 125, a photoactive layer 135 disposed on the hole transporting layer 130, an electron transporting layer 140 disposed on the photoactive layer 135 and the graphene intermediate layer 105, which serves as a recombination contact zone for subcell 110, disposed on the electron transporting layer 140. The photoactive subcell 115 comprises the graphene intermediate layer 105 which serves as a recombination contact zone for this subcell, a hole transporting layer 145 disposed on the graphene layer 105, a photoactive layer 150 disposed on the hole transporting layer 145, an electron transporting layer 155 disposed on the photoactive layer 150 and an electrode 160 disposed on the electron transporting layer 155.

As shown in FIG. 1, the photoactive subcell 110 and the photoactive subcell 115 have an electrical connection between electrodes 125 and 160 that is used to drive an external load 165. In one embodiment, the top electrode 160 of the series tandem photovoltaic cell 100 can be a cathode, while the bottom electrode 125 can function as an anode.

In one embodiment, the substrate 110 for the series tandem photovoltaic cell 100 is an insulating substrate that can either be optically transparent or opaque. For an optically transparent substrate, rigid glass, quartz or a flexible plastic material (e.g., polyesters, polyamides, polycarbonates, polyethylene, polyethylene products, polymethyl methacrylates, their copolymers or any combination thereof) can be used to form the substrate for the series tandem photovoltaic cell 100. For an opaque substrate, ceramics or semiconducting materials can be used to form the substrate for the series tandem photovoltaic cell 100.

In one embodiment, the electrode 125 in the series tandem photovoltaic cell 100 can be formed of an electrically conductive material. This material can comprise a material or combinations of material from the group including, but not limited to, metal oxides (e.g. indium tin oxide (ITO), fluorine-doped tin oxide, indium-doped zinc oxide, nickel-tungsten oxide, cadmium-tin oxide, etc), pristine/doped/functionalized graphene films, graphene flakes, reduced graphene oxide, carbon nanotubes/rods, metal mesh, metal grids, metals, metal alloys, and electrically conducting polymers. In a preferred embodiment, ITO can be used as the electrode material for the conductive electrode 125 because of its high conductivity and high work function. In one embodiment, the electrode 125 has a work function that is greater than 4.5 eV.

In one embodiment, the hole-transporting layers 130 and 145 can be a material that has a high mobility of hole carriers. For example, the hole transporting layers 130 and 145 can include, but are not limited to, doped poly(3,4-ethylene dioxythiophene) (PEDOT), or poly(3,4-ethylenedioxythiophene)poly(styrenesulfonate) (PEDOT:PSS), polyanilines, polyvinylcarbazoles, polyphenylenes, inorganic oxides (e.g. molybdenum oxide, tungsten oxide, etc), copolymers, graphene oxide, reduced graphene oxide, graphene flakes, and liquid electrolyte, thereof.

In one embodiment, the photoactive layers 135 and 150 can include a layer/blended layer of an electron donor and an electron acceptor. For example, electron donors can include p-type materials in which the principle charge carriers are holes. This enables good hole extraction into the conductive electrode 125. Electron donor material can include a material or combinations of materials from the group including, but not limited to, conjugated polymers such as polythiophenes (e.g. poly(3-hexylthiophene) or named as P3HT), polyanilines, polycarbazoles, polyninylcarbazoles, polyphenylenes, polyphenylvinylenes, polysilanes, polythiazoles, poly(thiophene oxide), phthalocyanine pigment (e.g. ZnPc, CuPc, 4F—ZnPc, SnPc, H₂Pc, etc), pentacenes, quantum dots, oligomers, dyes, semiconductor materials such as group IV semiconductor materials (e.g. silicon and germanium), group III-V semiconductor materials (e.g. indium phosphide, gallium arsenide, etc), group II-VI semiconductor materials (e.g. cadmium selenide, cadmium telluride, etc), and chalcogen semiconductor materials (e.g. copper indium selenide, copper indium gallium selenide, etc). Electron acceptors are typically n-type materials in which the principle charge carriers are electrons. This enables good electron extraction into the conductive electrode 160. Electron acceptor material can comprise a material or combinations of material from the group including, but not limited to, fullerenes (e.g. C60, etc), substituted fullerenes (e.g. [6,6]-phenyl-C61-butyric acid methyl ester (PCBM), etc), carbon nanomaterials (e.g. graphene oxide, reduced graphene oxide, functionalized graphene oxide, carbon nanotubes, carbon nanorods, etc), quantum dots, oligomers, quantum dots, oligomers, dyes, semiconductor materials such as group IV semiconductor materials (e.g. silicon and germanium), group III-V semiconductor materials (e.g. indium phosphide, gallium arsenide, etc), group II-VI semiconductor materials (e.g. cadmium selenide, cadmium telluride, etc), chalcogen semiconductor materials (e.g. copper indium selenide, copper indium gallium selenide, etc), inorganic nanomaterials, inorganic semiconductors (e.g. zinc oxide, titanium oxide, etc), polymers containing CN groups, polymers containing CF₃ groups, perylene tetracarboxylic acid bisimidazole, and pyrimidines.

In one embodiment, the electron-transporting layer 140 and 155 can be a material that has a high mobility of electron carriers. In the various embodiments Of the present invention, the electron transporting layers 140 and 155 can include, but are not limited to, zinc oxide, titanium oxide, bathophenanthroline, 2,9-dimethyl-4,7-diphenyl-1,10-phenanthroline.

In one embodiment, the electrode 160 in the series tandem photovoltaic cell 100 can be formed of an electrically conductive material. This material can comprise a material or combination of materials from the group including, but not limited to, metal oxides (e.g. indium tin oxide (ITO), fluorine-doped tin oxide, indium-doped zinc oxide, nickel-tungsten oxide, cadmium-tin oxide, etc), pristine/doped/functionalized graphene films, graphene flakes, reduced graphene oxide, carbon nanotubes/rods, metal mesh, metal grids, metals, metal alloys, organic material modified metal (e.g. LiF/Al, CsF/Al, etc), and electrically conducting polymers. In one embodiment, the LiF/Al layer can serve as the commonly used cathode that can enhance electron injection in the series tandem photovoltaic cell 100. This conductive electrode contact can have a work function that is less than 4.5 eV.

In one embodiment, the graphene intermediate layer 105 can be a film of graphene. The graphene film can comprise a single layer of graphene or more than one layer of graphene. In one embodiment, the graphene film layer can comprise a modified form of graphene film. For example, the modified form of graphene film can comprise molybdenum oxide (MoO₃), vanadium oxide (V₂O₅), tungsten oxide (WO₃), poly[(9,9-bis((6′-(N,N,Ntrimethylammonium)hexyl)-2,7-fluorene)-alt-(9,9-bis(2-(2-(2-methoxyethoxy)ethoxy)ethyl)-9-fluorene))dibromide (WPF-6-oxy-F), poly(ethylene oxide) (PEO), alkali carbonate (e.g. Cs₂CO₃, Rb₂CO₃, K₂CO₃, Na₂CO₃, Li₂CO₃), etc. In one embodiment, the graphene film can have a thickness that is greater than 0.5 nm. In one embodiment, the graphene film has a thickness that ranges from about 0.5 nm to about 30 nm.

The graphene intermediate layer 105 is suitable for use as an interlayer in the series tandem photovoltaic cell 100 because it has a sheet resistance that is less than 1 k ohm per square. A low sheet resistance will facilitate effective collection of charge carriers. Furthermore, the graphene intermediate layer 105 has an optical transparency that is greater than 80% at 550 nm. Note that a high transparency intermediate layer will not affect the light absorption behavior of the photoactive layers coupled thereto. In addition, the pristine/doped/functionalized graphene intermediate layer has a work function that can range from about 3 eV to about 5.5 eV which enables it to be tunable to match up with the various energy levels of the photoactive layers of the subcells that are supported by and electrically connected thereto.

In operation of the series tandem photovoltaic cell 100, the graphene intermediate layer 105 can serve as a recombination contact zone. In particular, the graphene intermediate layer 105 is inserted between the adjacent subcells as a recombination zone for electrons and holes from their respective subcells. In one embodiment, the graphene intermediate layer 105 is configured to let both positive and negative charges recombine from the first photoactive subcell 110 and the second photoactive subcell 115. As a result, the graphene intermediate layer 105 can prevent the build-up of charges, introduce the adequate Fermi level alignment between the adjacent photoactive subcells and ensure the maximized open circuit voltage. In this embodiment, the electrode 125 of the first photoactive subcell 110 is used as an electrical contact to collect holes while the electrode 160 of the second photoactive subcell 115 is configured as an electrical contact to collect electrons. In one embodiment, the electrode 125 collecting holes can have a work function that is greater than 4.5 eV, while the electrode 160 collecting electrons can have a work function that is less than 4.5 eV.

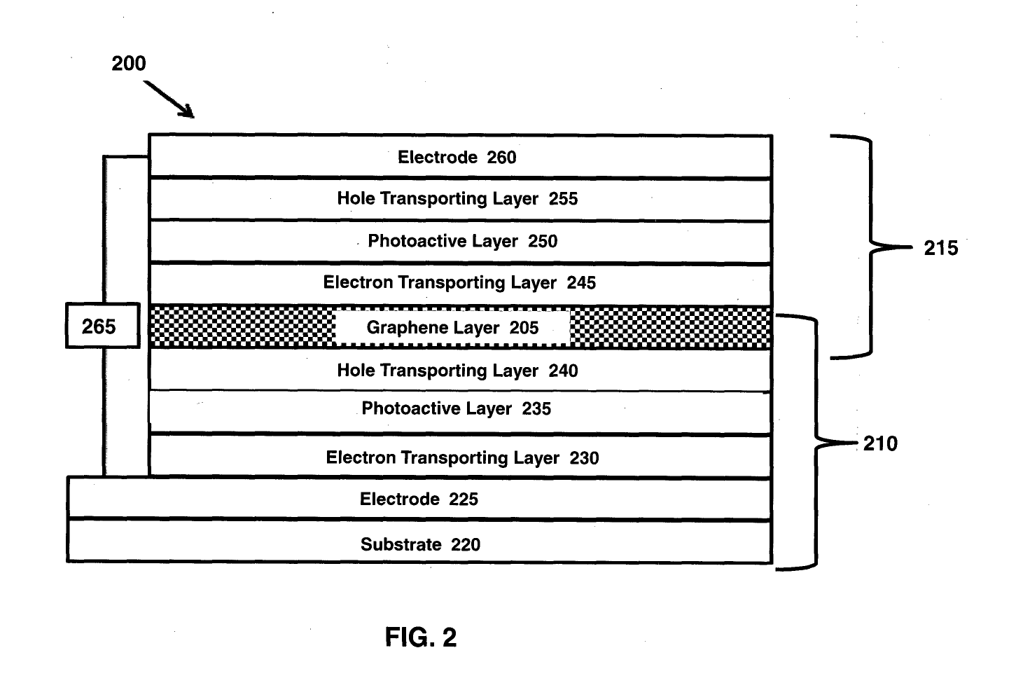

FIG. 2 is a schematic diagram of a series tandem photovoltaic cell 200 according to another embodiment of the present invention. In particular, the series tandem photovoltaic cell 200 is representative of an inverted device structure of the series tandem photovoltaic cell 100 depicted in FIG. 1. The series tandem photovoltaic cell 200 is an inverted device structure of the series tandem photovoltaic cell 100 in that the hole transporting layers and the electron transporting layers in the photoactive subcells have been inverted. As shown in FIG. 2, a graphene intermediate layer 205 is interposed between two photoactive subcells 210 and 215. Like FIG. 1, the graphene intermediate layer 205 provides an electrical connection between the photoactive subcell 210 and the photoactive subcell 215 such that the photoactive subcells are electrically coupled in series. The photoactive subcell 210 comprises a substrate 220, an electrode 225 disposed on the substrate 220, an electron transporting layer 230 disposed on the electrode 225, a photoactive layer 235 disposed on the electron transporting layer 230, a hole transporting layer 240 disposed on the photoactive layer 235 and the graphene intermediate layer 205, which serves as a recombination contact zone for subcell 210, disposed on the hole transporting layer 240. The photoactive subcell 215 comprises the graphene intermediate layer 205 which serves as a recombination contact zone for this subcell, an electron transporting layer 245 disposed on the graphene layer 205, a photoactive layer 250 disposed on the electron transporting layer 245, a hole transporting layer 255 disposed on the photoactive layer 250 and an electrode 260 disposed on the hole transporting layer 255.

As shown in FIG. 2, the photoactive subcell 210 and the photoactive subcell 215 have an electrical connection between electrodes 225 and 260 that is used to drive an external load 265. In one embodiment, the top electrode 260 of the series tandem photovoltaic cell 200 can be an anode, while the bottom electrode 225 can function as a cathode.

The materials described for the substrate 220, the electrode 225, the electron transporting layer 230, the photoactive layer 235, the hole transporting layer 240 and the graphene intermediate layer 205 in photoactive subcell 210 can be the same material mentioned above for their counterparts used in the photoactive subcell 110 of FIG. 1, and therefore a separate description of the material used for each layer in subcell 210 is not provided. Likewise, the electron transporting layer 245, the photoactive layer 250, the hole transporting layer 255 and the electrode 260 in photoactive subcell 215 can be the same material mentioned above for their counterparts used in the photoactive subcell 115 of FIG. 1, and therefore a separate description of the material used for each layer in subcell 215 is not provided. All that differs between the photoactive subcells 210 and 215 in FIG. 2 and the photoactive subcells 110 and 115 in FIG. 1 is that the position of some of the layers in these subcells has been inverted.

Like the operation of the series tandem photovoltaic cell 100, the graphene intermediate layer 205 in series tandem photovoltaic cell 200 can serve as a recombination contact zone. In particular, the graphene intermediate layer 205 is inserted between the adjacent subcells as a recombination zone for electrons and holes from their respective subcells. In one embodiment, the graphene intermediate layer 205 is configured to let both positive and negative charges recombine from the first photoactive subcell 210 and the second photoactive subcell 215. As a result, the graphene intermediate layer 205 can prevent the build-up of charges, introduce the adequate Fermi level alignment between the adjacent photoactive subcells and ensure the maximized open circuit voltage. In this embodiment, the electrode 225 of the first photoactive subcell 210 is configured as an electrical contact to collect electrons while the electrode 260 of the second photoactive subcell 215 is configured as an electrical contact to collect holes. In one embodiment, the electrode 260 collecting holes can have a work function that is greater than 4.5 eV, while the electrode 225 collecting electrons can have a work function that is less than 4.5 eV.

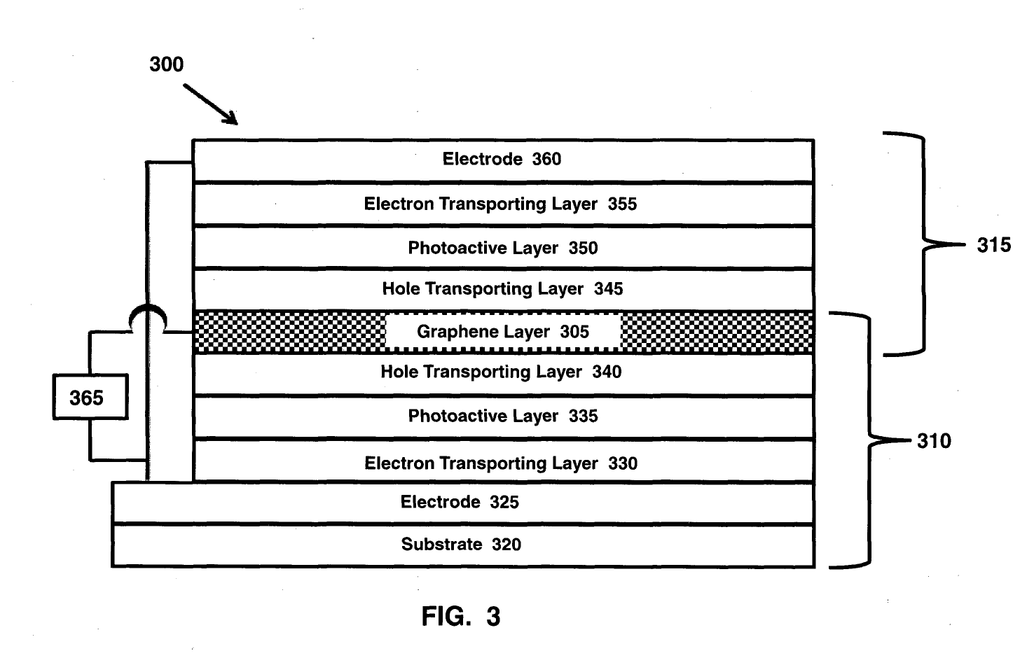

FIG. 3 is a schematic diagram of another tandem solar cell also referred to herein as a tandem photovoltaic cell according to one embodiment of the present invention. In particular, FIG. 3 shows a parallel tandem photovoltaic cell 300 in which a graphene intermediate layer 305 is interposed between two photoactive subcells 310 and 315. In one embodiment, the graphene intermediate layer 305 provides an electrical connection between the photoactive subcell 310 and the photoactive subcell 315. As shown in FIG. 3, the photoactive subcell 310 and the photoactive subcell 315 are electrically coupled in parallel. The photoactive subcell 310 comprises a substrate 320, an electrode 325 disposed on the substrate 320, an electron transporting layer 330 disposed on the electrode 325, a photoactive layer 335 disposed on the electron transporting layer 330, a hole transporting layer 340 disposed on the photoactive layer 335 and the graphene intermediate layer 305, which serves as an electrode for subcell 310, disposed on the hole transporting layer 340. The photoactive subcell 315 comprises the graphene intermediate layer 305 which serves as an electrode for this subcell, a hole transporting layer 345 disposed on the graphene layer 305, a photoactive layer 350 disposed on the hole transporting layer 345, an electron transporting layer 355 disposed on the photoactive layer 350 and an electrode 360 disposed on the electron transporting layer 355.

As shown in FIG. 3, the photoactive subcell 310 and the photoactive subcell 315 have an electrical connection between the electrodes 325 and 360. In addition, the photoactive subcell 310 and the photoactive subcell 315 share a common electrode 305 (i.e., the graphene layer). The common electrode 305 and the electrodes 325 and 360 are used to drive an external load 365. As shown in FIG. 3, these electrical connections are in parallel with each other. In one embodiment, the electrodes 325 and 360 of the parallel tandem photovoltaic cell 300 can be a cathode, while the graphene layer 305 which is the intermediate layer in the cell can function as the common anode.

In one embodiment, the substrate 320 for the parallel tandem photovoltaic cell 300 is an insulating substrate that can either be optically transparent or opaque. For an optically transparent substrate, rigid glass, quartz or a flexible plastic material (e.g., polyesters, polyamides, polycarbonates, polyethylene, polyethylene products, polymethyl methacrylates, their copolymers or any combination thereof) can be used to form the substrate for the parallel tandem photovoltaic cell 300. For an opaque substrate, ceramics or semiconducting materials can be used to form the substrate for the parallel tandem photovoltaic cell 300.

In one embodiment, the electrode 325 can be formed of an electrically conductive material in the parallel tandem photovoltaic cell 300. This material can comprise a material or combinations of from the group including, but not limited to, the metal oxides (e.g. indium tin oxide (ITO), fluorine-doped tin oxide, indium-doped zinc oxide, nickel-tungsten oxide, cadmium-tin oxide, etc), pristine/doped/functionalized graphene films, graphene flakes, reduced graphene oxide, carbon nanotubes/rods, metal mesh, metal grids, metals, metal alloys, and electrically conducting polymers. In a preferred embodiment, ITO can be used as the electrode material for the conductive electrode 325 because of its high conductivity and high work function. In one embodiment, the electrode 325 has a work function that is greater than 4.5 eV.

In one embodiment, the hole-transporting layers 340 and 345 can be a material that has a high mobility of hole carriers. For example, the hole transporting layers 340 and 345 can include, but are not limited to, doped poly(3,4-ethylene dioxythiophene) (PEDOT), or poly(3,4-ethylenedioxythiophene)poly(styrenesulfonate) (PEDOT:PSS), polyanilines, polyvinylcarbazoles, polyphenylenes, molybdenum oxide, tungsten oxide and copolymers, graphene oxide, reduced graphene oxide, graphene flakes, and liquid electrolyte thereof.

In one embodiment, the photoactive layer 335 and 350 can include a layer/blended layer of an electron donor and an electron acceptor. For example, electron donors can include p-type materials in which the principle charge carriers are holes. This enables good hole extraction into the conductive electrode 325. Electron donor material can comprise a material or combinations of material from the group including, but not limited to, conjugated polymers such as polythiophenes (e.g. poly(3-hexylthiophene) or named as P3HT), polyanilines, polycarbazoles, polyninylcarbazoles, polyphenylenes, polyphenylvinylenes, polysilanes, polythiazoles, poly(thiophene oxide), phthalocyanine pigment (e.g. ZnPc, CuPc, 4F—ZnPc, SnPc, H₂Pc, etc), pentacenes, quantum dots, oligomers, dyes, semiconductor materials such as group IV semiconductor materials (e.g. silicon and germanium), group III-V semiconductor materials (e.g. indium phosphide, gallium arsenide, etc), group II-VI semiconductor materials (e.g. cadmium selenide, cadmium telluride, etc), and chalcogen semiconductor materials (e.g. copper indium selenide, copper indium gallium selenide, etc). Electron acceptors are typically n-type materials in which the principle charge carriers are electrons. This enables good electron extraction into the conductive electrode 360. Electron acceptor material can comprise a material or combinations of material from the group including, but not limited to, fullerenes (e.g. C60, etc), substituted fullerenes (e.g. [6,6]-phenyl-C61-butyric acid methyl ester (PCBM), etc), carbon nanomaterias (e.g. graphene oxide, reduced graphene oxide, functionalized graphene oxide, carbon nanotubes, carbon nanorods, etc), quantum dots, oligomers, quantum dots, oligomers, dyes, semiconductor materials such as group IV semiconductor materials (e.g. silicon and germanium), group III-V semiconductor materials (e.g. indium phosphide, gallium arsenide, etc), group II-VI semiconductor materials (e.g. cadmium selenide, cadmium telluride, etc), chalcogen semiconductor materials (e.g. copper indium selenide, copper indium gallium selenide, etc), inorganic nanomaterials, inorganic semiconductors (e.g. zinc oxide, titanium oxide, etc), polymers containing CN groups, polymers containing CF₃ groups, perylene tetracarboxylic acid bisimidazole, and pyrimidines.

In one embodiment, the electron-transporting layer 330 and 355 can be a material that has a high mobility of electron carriers. In the various embodiments of the present invention, the electron transporting layers 330 and 355 can include, but are not limited to, zinc oxide and titanium oxide.

In one embodiment, the conductive electrode 360 can be formed of an electrically conductive material in the parallel tandem photovoltaic cell 300. This material can comprise a material or combinations of material from the group including, but not limited to, metal oxides (e.g. indium tin oxide (ITO), fluorine-doped tin oxide, indium-doped zinc oxide, nickel-tungsten oxide, cadmium-tin oxide, etc), pristine/doped/functionalized graphene films, graphene flakes, reduced graphene oxide, carbon nanotubes/rods, metal mesh, metal grids, metals, metal alloys, organic material modified metal (e.g. LiF/Al, CsF/Al, etc), and electrically conducting polymers. In one embodiment, the LiF/Al layer can serve as the commonly used cathode that can enhance electron injection in the parallel tandem photovoltaic cell 300. This conductive electrode contact can have a work function that is less than 4.5 eV.

In one embodiment, the graphene intermediate layer 305 can be a film of graphene. The graphene film can comprise a single layer of graphene or more than one layer of graphene. In one embodiment, the graphene film layer can comprise a modified form of graphene film. For example, the modified form of graphene film can comprise molybdenum oxide (MoO₃), vanadium oxide (V₂O₅), tungsten oxide (WO₃), poly[(9,9-bis((6′-(N,N,Ntrimethylammonium)hexyl)-2,7-fluorene)-alt-(9,9-bis(2-(2-(2-methoxyethoxy)ethoxy)ethyl)-9-fluorene))dibromide (WPF-6-oxy-F), poly(ethylene oxide) (PEO), alkali carbonate- (e.g. Cs₂CO₃, Rb₂CO₃, K₂CO₃, Na₂CO₃, Li₂CO₃), etc. In one embodiment, the graphene film can have a thickness that is greater than 0.5 nm. In one embodiment, the graphene film has a thickness that ranges from about 0.5 nm to about 30 nm.

The graphene intermediate layer 305 is suitable for use as an interlayer in the parallel tandem photovoltaic cell 300 because it has a sheet resistance that is less than 1 k ohm per square. Furthermore, the graphene intermediate layer 305 has an optical transparency that is greater than 80%. In addition, the pristine/doped/functionalized graphene intermediate layer has a work function that can range from about 3 eV to about 5.5 eV which enables it to be tunable to match up with the various energy levels of the photoactive layers of the subcells that are supported by and electrically connected thereto.

In operation of the parallel tandem photovoltaic cell 300, the graphene intermediate layer 305 can serve as a common electrode to the first photoactive subcell 310 and the second photoactive subcell 315. In one embodiment, the graphene intermediate layer 305 collects holes generated from the first photoactive subcell 310 and the second photoactive subcell 315, while the electrodes 325 and 360 can be used as electrical contacts to collect electrons generated from the photoactive subcells. In one embodiment, the electrode collecting holes (graphene intermediate layer 305) can have a work function that is greater than 4.5 eV, while the electrode collecting electrons (electrodes 325 and 360) can have a work function that is less than 4.5 eV.

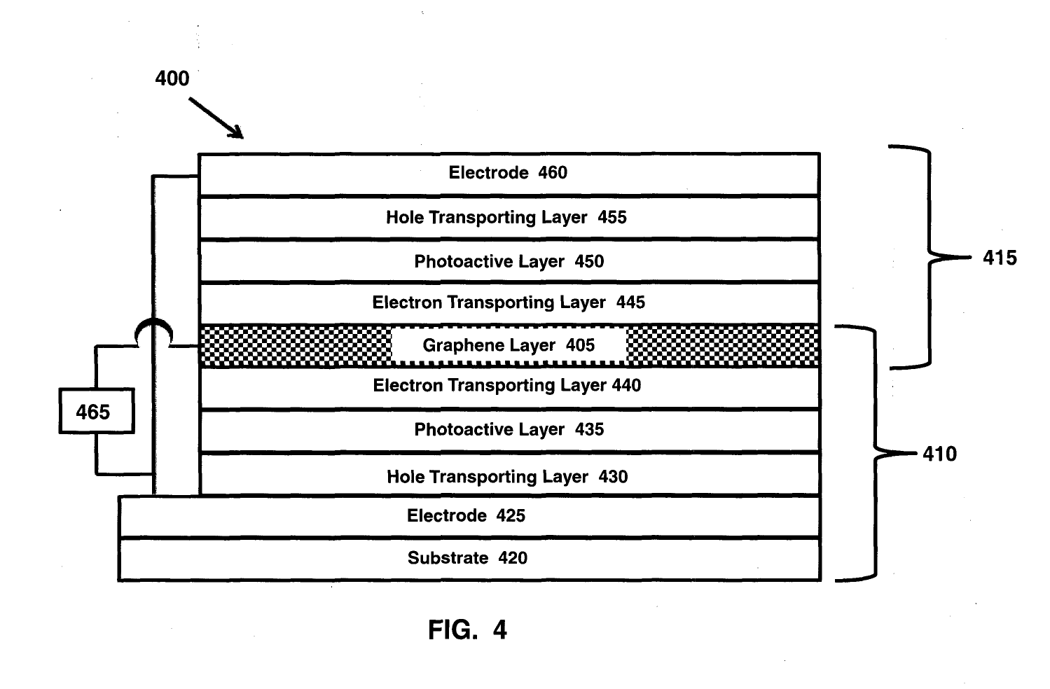

FIG. 4 is a schematic diagram of a parallel tandem photovoltaic cell 400 according to another embodiment of the present invention. In particular, the parallel tandem photovoltaic cell 400 is representative of an inverted device structure of the parallel tandem photovoltaic cell 300 depicted in. FIG. 3. The parallel tandem photovoltaic cell 400 is an inverted device structure of the parallel tandem photovoltaic cell 300 in that the hole transporting layers and the electron transporting layers in the photoactive subcells have been inverted. As shown in FIG. 4, a graphene intermediate layer 405 is interposed between two photoactive subcells 410 and 415. Like FIG. 3, the graphene intermediate layer 405 provides an electrical connection between the photoactive subcell 410 and the photoactive subcell 415 such that the photoactive subcells are electrically coupled in parallel. The photoactive subcell 410 comprises a substrate 420, an electrode 425 disposed on the substrate 420, a hole transporting layer 430 disposed on the electrode 425, a photoactive layer 435 disposed on the hole transporting layer 430, an electron transporting layer 440 disposed on the photoactive layer 435 and the graphene intermediate layer 405, which serves as an electrode for subcell 410; disposed on the electron transporting layer 440. The photoactive subcell 415 comprises the graphene intermediate layer 405 which serves as an electrode for this subcell, an electron transporting layer 445 disposed on the graphene layer 405, a photoactive layer 450 disposed on the electron transporting layer 445, a hole transporting layer 455 disposed on the photoactive layer 450 and an electrode 460 disposed on the hole transporting layer 455.

As shown in FIG. 4, the photoactive subcell 410 and the photoactive subcell 415 have an electrical connection between the electrodes 425 and 460. In addition, the photoactive subcell 410 and the photoactive subcell 415 share a common electrode 405 (i.e., the graphene layer). The common electrode 405 and the electrodes 425 and 460 are used to drive an external load 465. In one embodiment, the electrodes 425 and 460 of the parallel tandem photovoltaic cell 400 can be an anode, while the graphene layer 405 which is the intermediate layer in the cell can function as the common cathode.

The materials described for the substrate 420, the electrode 425, the hole transporting layer 430, the photoactive layer 435, the electron transporting layer 440 and the graphene intermediate layer 405 in photoactive subcell 410 can be the same material mentioned above for their counterparts used in the photoactive subcell 310 of FIG. 3, and therefore a separate description of the material used for each layer in subcell 410 is not provided. Likewise, the electron transporting layer 445, the photoactive layer 450, the hole transporting layer 455 and the electrode 460 in photoactive subcell 415 can be the same material mentioned above for their counterparts used in the photoactive subcell 315 of FIG. 3, and therefore a separate description of the material used for each layer in subcell 415 is not provided. All that differs between photoactive subcells 410 and 415 and photoactive subcells 310 and 315 is that the position of some of the layers in these subcells has been inverted.

Like the operation of the parallel tandem photovoltaic cell 300, the graphene intermediate layer 405 in parallel tandem photovoltaic cell 400 can serve as a common electrode to the first photoactive subcell 410 and the second photoactive subcell 415. In one embodiment, the graphene intermediate layer 405 collects electrons generated from the first photoactive subcell 410 and the second photoactive subcell 415, while the electrodes 425 and 460 can be used as electrical contacts to collect holes generated from the photoactive subcells. In one embodiment, the electrodes collecting holes (electrodes 425 and 460) can have a work function that is greater than 4.5 eV, while the electrode collecting electrons (graphene intermediate layer 405) can have a work function that is less than 4.5 eV.

Although FIGS. 1-4 illustrate a tandem photovoltaic cell with only two photoactive subcells, it is not meant to limit the scope of the various embodiments of the present invention. Those skilled in the art will appreciate that the various embodiments of the present invention are suitable for a tandem photovoltaic cell that can have two or more photoactive subcells whether the photovoltaic cell is a series-type or a parallel-type. For a tandem photovoltaic cell that has two or more photoactive subcells, a graphene film layer can be disposed between each pair of photoactive subcells in the tandem photovoltaic cell. In this embodiment, each graphene film layer would provide an electrical connection between each pair of photoactive subcells.

The use of the graphene intermediate layer as described in FIGS. 1-4 provides the series tandem photovoltaic cells 100 and 200, the parallel tandem photovoltaic cells 300 and 400, and other such tandem photovoltaic cell devices with the capability of easily being manufactured and has the potential for creating flexible photovoltaic cell devices. In particular, since the graphene intermediate layers as described in FIGS. 1-4 have good conductivity (less than 1 k ohm per square) and high transparency (greater than 80% at 550 nm), each photoactive layer within a photoactive subcell can absorb a different wavelength range of solar spectrum. This provides marked improvement in comparison to conductive metallic thin films that are used as an interlayer in tandem solar cells, which block a large portion of incident light from reaching a photoactive layer because of their low optical transparency. The optical light loss problem associated with conductive metallic thin films is only exasperated as the number of subcells and intermediate layers used in the tandem solar cell structure increases. The use of graphene as an intermediate layer in a tandem photovoltaic cell structures obviates this concern.

Another advantage of using a graphene intermediate layer in a tandem photovoltaic cell in comparison to conductive metallic thin films is that a single substrate can be used as opposed to two separate substrates for each photoactive subcell. In this manner, the photoactive subcells are stacked on the one subcell attached to the substrate. Graphene has the mechanical strength that makes it suitable to support stacks of photoactive subcells.

Furthermore, the graphene intermediate layer has a tunable work function that enables an easy match-up with the energy levels of the photoactive layers of the photoactive subcells used in tandem photovoltaic cells. As a result, tandem photovoltaic cells that use a graphene intermediate layer positioned between photoactive subcells to make an electrical connection therebetween will result in a tandem photovoltaic cell device with improved solar cell efficiency. A tandem photovoltaic cell device made from organic and polymer material with improved solar cell efficiency as provided herein makes such devices well suited to function as portable electricity sources (e.g., as a charger) for portable electronic devices (e.g., mobile phone, digital cameras, handheld games, notebook computers).

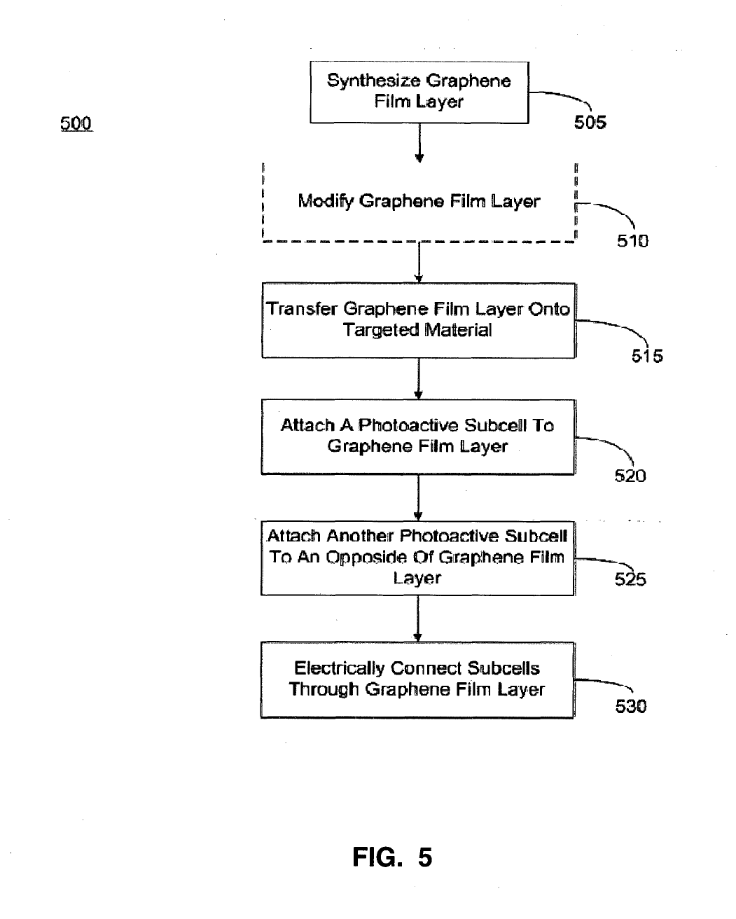

FIG. 5 is a flow chart 500 describing a method for fabricating a tandem photovoltaic cell such as the ones depicted in FIGS. 1-4 according to one embodiment. The method of fabricating a tandem photovoltaic cell begins by obtaining a graphene film layer. In FIG. 5, the graphene film is synthesized at 505. In one embodiment, synthesizing the graphene film layer can include growing the graphene film layer with copper (Cu) or nickel (Ni) on a semiconductor wafer using a chemical vapor deposition (CVD) process. Those skilled in the art will appreciate that the graphene film layer can be synthesized in other manners. A non-exhaustive list of approaches that can be used to synthesize the graphene film layer can include using solid phase growth (e.g., from a catalytically decomposed polymer) and solution-processed graphene derivatives (e.g., graphene oxide, reduced graphene oxide, exfoliated graphene flakes).

Upon synthesizing the graphene film layer can be optionally (designed by the use of dotted lines) modified at 510. In particular, in one embodiment, the grown graphene film layer can be doped with a conductivity-enhancing dopant. Doping the graphene film layer with a conductivity-enhancing dopant can be based on the principle of surface transfer doping. The dopants can include, but not limited to, hydrochloric acid (HCl), nitric acid (HNO₃), gold (III) chloride (AuCl₃), trifluoromethanesulfonyl-amide (TFSA), tetra-fluoro-7,7,8,8-tetracyanoquinodimethane (F4-TCNQ), tetracyanoquinodimethane (TCNQ), etc.

In another embodiment, the grown graphene film layer can be functionalized with a work function-modifying or wetting properties modifier layer that can provide the best energy level alignment and interfacial morphology with an adjacent hole or electron transporting layer. For example, such a modifier layer can be based on a nanostructured polymer such as nano-PEDOT or PEDOT:PSS. PEDOT=Poly(3,4-ethylenedioxythiophene) PSS=poly(styrenesulfonate) PEDOT, molybdenum oxide (MoO₃), vanadium oxide (V₂O₅), tungsten oxide (WO₃), poly[(9,9-bis((6′-(N,N,Ntrimethylammonium)hexyl)-2,7-fluorene)-alt-(9,9-bis(2-(2-(2-methoxyethoxy)ethoxy)ethyl)-9-fluorene))dibromide (WPF-6-oxy-F), poly(ethylene oxide) (PEO), alkali carbonate- (e.g. Cs₂CO₃, Rb₂CO₃, K₂CO₃, Na₂CO₃, Li₂CO₃), etc.

Referring back to the flow chart 500 of FIG. 5, the grown graphene film layer (or modified grown graphene film layer) can then be transferred onto a targeted material at 515. This targeted material can include, but is not limited to, a polydimethylsiloxane (PDMS) stamp and a thermal release tape. In one embodiment, dry transfer technology based on a PDMS stamp can be used to transfer the grown graphene film layer on a quartz substrate.

For the embodiment in which a CVD process is used to grow the graphene film layer, targeted materials will act as a mechanical support until Cu or Ni metal is completely etched from the graphene film layer. After the etching process, the graphene can then be transferred from the targeted material.

At 520, graphene film layer is transferred and attached to one of the organic photoactive subcells. In one embodiment, the transferring and attaching can include pressing the graphene film layer onto one of the subcells and applying heat to release the PDMS or tape if being used. Another organic photoactive subcell can then be attached to the graphene film layer onto a side of the graphene film layer that opposes the attachment of the other subcell at 525. In one embodiment, solution processing, thermal evaporation, roll-to-roll processing, stamping can be used to deposit the organic layers and electrodes of the other photoactive subcell.

Next, as shown in FIG. 5, the photoactive subcells are electrically connected through the graphene film layer at 530. In one embodiment, the photoactive subcells are electrically connected through the graphene film layer in order to provide the selective contact of the same polarity (either p-type or n-type) to the subcells. For a tandem solar cell in series connection, the graphene film layer is the middle electrical contact for the recombination of holes in one subcell and electrons from adjacent subcells, while the remaining free charge carriers are collected at the outer electrodes. For the tandem solar cell in parallel connection, the graphene film layer acts as the electrode to collect holes (electrons) while the outer electrodes are both used as electrical contacts to collect electrons (holes).

The foregoing flow chart set forth in FIG. 5 shows some of the processing functions associated with fabricating a tandem photovoltaic cell according to the various embodiments of the present invention. In this regard, each block represents a process act associated with performing these functions. It should also be noted that in some alternative implementations, the acts noted in the blocks may occur out of the order noted in the figure or, for example, may in fact be executed substantially concurrently or in the reverse order, depending upon the act involved. Also, one of ordinary skill in the art will recognize that additional blocks that describe the processing functions may be added.

### EXAMPLES

The following provides particular examples of synthesizing a graphene layer for use as an intermediate layer in a tandem photovoltaic cell, and fabricating a series tandem photovoltaic cell and a parallel tandem photovoltaic cell according to embodiments described herein.

### Example 1

### Preparation of a Graphene Intermediate Layer

In this example, a large area (1×1 cm²) graphene film is synthesized on a copper (Cu) or nickel (Ni) coated SiO₂/Si wafer by using a chemical vapor deposition (CVD) process. The Cu or Ni film was then etched away by using iron chloride, ferric nitrate, ammonium persulphate, sodium persulfate and a hydrochloric acid solution. Dry transfer technology based on polydimethylsiloxane (PDMS) stamp was applied to transfer the graphene film on a targeted material. The thickness of the graphene film in this example ranged from about 0.5 nm to about 30 nm.

### Example 2

### A Series Tandem Solar Cell with a Graphene Intermediate Layer

In this example, the device structure of the series tandem solar cell depicted in FIG. 1 was fabricated. In particular, a two-terminal series connected tandem cell was designed to extract holes and electrons by using a transparent indium tin oxide (ITO) anode and a thermally evaporated LiF/Al cathode. Spin coated PEDOT:PSS and thermally evaporated MoO₃ were used as a hole transporting layer. In this example, the graphene intermediate layer acts as recombination contact zone that is transferred from a PDMS stamp onto a photoactive layer. Photoactive layers with distinct complementary absorption ranges were selected. In particular, the photoactive layers comprised two bulk heterojunction active layers stacked on top of each other. More specifically, a spin coated poly(3-hexylthiophene-2,5-diyl):[6,6]-phenyl C61 butyric acid methyl ester (P3HT:PCBM) was used as a photoactive layer 1 for a bottom subcell and a thermally evaporated zinc phthalocyanine:fullerene (ZnPc:C60) was used as a photoactive layer 2 for a top subcell.

### Example 3

### A Parallel Tandem Solar Cell with a Graphene Intermediate Layer

In this example, the device structure of the parallel tandem solar cell depicted in FIG. 3 was fabricated. In particular, a three-terminal parallel connected tandem cell was designed to extract holes through the graphene intermediate layer (common anode) and collect electrons through an ITO and thermally evaporated LiF/Al cathodes. Thermally evaporated MoO₃ was used as a hole transporting layer. In this example, the graphene intermediate layer was transferred from a PDMS stamp onto a photoactive layer. Photoactive layers with distinct complementary absorption range were selected. In particular, the photoactive layers comprised two bulk heterojunction active layers stacked on top of each other. More specifically, a spin coated poly(3-hexylthiophene-2,5-diyl):[6,6]-phenyl C61 butyric acid methyl ester (P3HT:PCBM) was used as the photoactive layer 1 for a bottom subcell and a thermally evaporated zinc phthalocyanine:fullerene (ZnPc:C60) was used as the photoactive layer 2 for a top subcell. In this example, ZnO was used as the electron transporting layer.

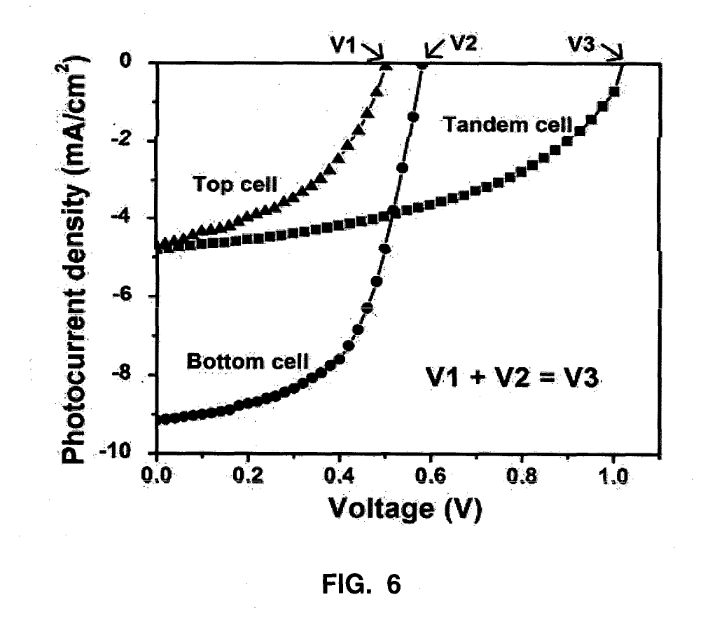

FIG. 6 is a graph that shows the photocurrent density as a function of the voltage under illumination of 100 mW/cm² for a series tandem photovoltaic cell like the ones depicted in FIGS. 1-2 and fabricated in a manner described in Example 2. In particular, FIG. 6 shows the photocurrent density-voltage (J-V) characteristics of the individual subcells (i.e., top cell (V1) and bottom cell (V2)) and an ideal series tandem photovoltaic cell device (V3). For the ideal series tandem cell, the theoretical open circuit voltage (V_{oc}) can be the sum of V_{oc} of each of the two photoactive subcells (V3=V1+V2). A tandem photovoltaic cell with a graphene intermediate layer as shown in FIG. 6 has a V_{oc} of 1V which is substantially equal to the theoretical V_{oc} of 1.08V. This confirms that a graphene intermediate layer functions well in a tandem photovoltaic solar cell without voltage loss.

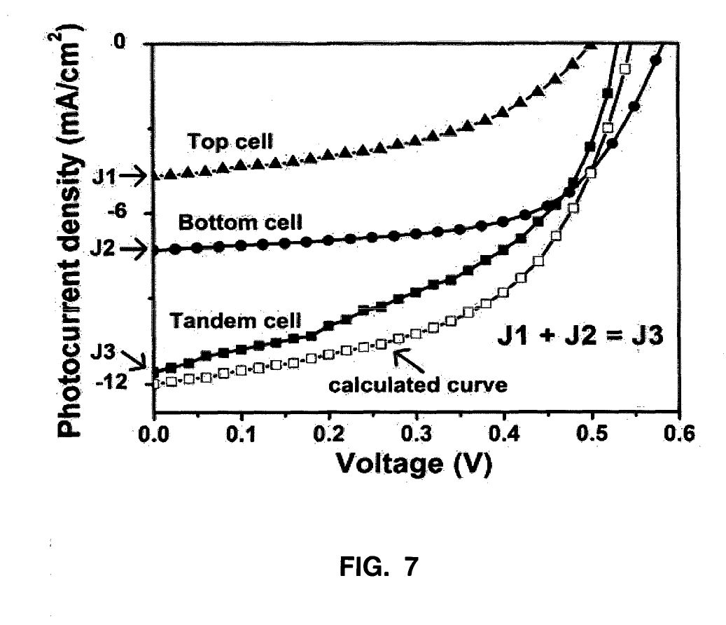

FIG. 7 is a graph that shows the photocurrent density as a function of the voltage under illumination of 100 mW/cm² for a tandem photovoltaic cell like the ones depicted in FIGS. 3-4 and fabricated in a manner described in Example 3. In particular, FIG. 7 shows the J-V characteristics of the individual photoactive subcells and an ideal parallel tandem photovoltaic cell device. In the ideal parallel tandem photovoltaic cell, the theoretical short circuit current density (J_{sc}) can be the sum of J_{sc} of two photoactive subcells. As shown in FIG. 7, a tandem photovoltaic cell with a graphene intermediate layer has a J_{sc} of 11.6 mA/cm² which is substantially equal to the theoretical J_{sc} of 12.3 mA/cm². Note that the calculated J-V curve of the tandem cell was plotted by adding the J-V curves of the two photoactive subcells (top cell and bottom cell) together. The nearly identical performance between the calculated curve and experimental results of the tandem cell suggests that graphene layer serves as an effective intermediate layer to provide high performance tandem cell in parallel. Even without perfect current matching between the top photoactive cell and the bottom photoactive cell, the power conversion efficiency of the parallel tandem cell can reach 2.9% which is 88% of the sum of two photoactive subcells.

Although the description of the use of a graphene film heretofore has been described with application to a solar cell device such as a photovoltaic cell, the various embodiments of the present invention has applicability beyond solar cell devices. For example, the use of graphene film as an intermediate layer can extend to a tandem optoelectronic device such as tandem light emitting diodes (LEDs) (e.g., organic LEDs, infrared (IR), or near IR LEDs). In one embodiment, a tandem optoelectronic device can include two or more optoelectronic active subcells. A graphene film layer can be disposed between each pair of optoelectronic active subcells in the two or more optoelectronic active subcells. In this embodiment, the graphene film layer provides an electrical connection between each pair of optoelectronic active subcells. In one embodiment, the graphene film layer provides a selective contact of the same polarity to each pair of optoelectronic active subcells to collect charges generated therefrom.

While the disclosure has been particularly shown and described in conjunction with a preferred embodiment thereof, it will be appreciated that variations and modifications will occur to those skilled in the art. Therefore, it is to be understood that the appended claims are intended to cover all such modifications and changes as fall within the true spirit of the disclosure.

1.-58. (canceled)

59. A tandem organic photovoltaic cell, comprising:
a first photoactive subcell;
a second photoactive subcell; and
an intermediate layer comprising graphene, disposed between the first photoactive subcell and the second photoactive subcell, that collects charges generated from the first photoactive subcell and the second photoactive subcell.

60. The tandem organic photovoltaic cell according to claim 59, wherein the first photoactive subcell and the second photoactive subcell are electrically coupled in series or in parallel.

61. The tandem organic photovoltaic cell according to claim 59, wherein the first photoactive subcell comprises a substrate, a first electrode disposed on the substrate, a first hole transporting layer disposed on the first electrode, a first photoactive layer disposed on the first hole transporting layer, a first electron transporting layer disposed on the first photoactive layer and a second electrode disposed over the first electron transporting layer.

62. The tandem organic photovoltaic cell according to claim 61, wherein the second photoactive subcell comprises a third electrode, a second hole transporting layer disposed on the third electrode, a second photoactive layer disposed on the second hole transporting layer, a second electron transporting layer disposed on the second photoactive layer and a fourth electrode disposed over the second electron transporting layer.

63. The tandem organic photovoltaic cell according to claim 59, wherein the first photoactive subcell comprises a substrate, a first electrode disposed on the substrate, a first electron transporting layer disposed on the first electrode, a first photoactive layer disposed on the first electron transporting layer, a first hole transporting layer disposed on the first photoactive layer and a second electrode disposed over the first hole transporting layer.

64. The tandem organic photovoltaic cell according to claim 63, wherein the second photoactive subcell comprises a third electrode, a second electron transporting layer disposed on the third electrode, a second photoactive layer disposed on the second electron transporting layer, a second hole transporting layer disposed on the second photoactive layer and a fourth electrode disposed over the second hole transporting layer.

65. The tandem organic photovoltaic cell according to claim 64, wherein the second electrode of the first photoactive subcell and the third electrode of the second photoactive subcell form a recombination contact zone that comprises the intermediate layer comprising graphene.

66. The tandem organic photovoltaic cell according to claim 65, wherein the recombination contact zone formed from the intermediate layer comprising graphene is configured to let both positive and negative charges recombine from the first photoactive subcell and the second photoactive subcell, and wherein the first electrode of the first photoactive subcell is configured as an electrical contact to collect holes or electrons while the fourth electrode of the second photoactive subcell is configured as an electrical contact to collect holes or electrons.

67. The tandem organic photovoltaic cell according to claim 59, wherein the first photoactive subcell comprises a substrate, a first electrode disposed on the substrate, a first hole transporting layer disposed on the first electrode, a first photoactive layer disposed on the first hole transporting layer, a first electron transporting layer disposed on the first photoactive layer and a second electrode disposed over the first electron transporting layer.

68. The tandem organic photovoltaic cell according to claim 67, wherein the second photoactive subcell comprises a third electrode, a second electron transporting layer disposed on the third electrode, a second photoactive layer disposed on the second electron transporting layer, a second hole transporting layer disposed on the second photoactive layer and a fourth electrode disposed over the second hole transporting layer.

69. The tandem organic photovoltaic cell according to claim 68, wherein the second electrode of the first photoactive subcell and the third electrode of the second photoactive subcell form a common electrode that comprises the intermediate layer comprising graphene.

70. The tandem organic photovoltaic cell according to claim 69, wherein the common electrode formed from the intermediate layer comprising graphene is configured to collect electrons generated from the first photoactive subcell and the second photoactive subcell, and wherein the first electrode of the first photoactive subcell and the fourth electrode of the second photoactive subcell are used as electrical contacts to collect holes generated from the first photoactive subcell and the second photoactive subcell.

71. The tandem organic photovoltaic cell according to claim 70, wherein the first electrode of the first photoactive subcell and the fourth electrode of the second photoactive subcell have an electrical connection.

72. A tandem photovoltaic cell, comprising:
two or more photoactive subcells;
a graphene film layer disposed between each pair of photoactive subcells in the two or more photoactive subcells, the graphene film layer providing an electrical connection between each pair of photoactive subcells, wherein the graphene film layer provides a selective contact of a same polarity to each pair of photoactive subcells to collect charges generated therefrom.

73. The tandem photovoltaic cell according to claim 72, wherein each pair of photoactive subcells in the two or more photoactive subcells are electrically coupled in series or in parallel.

74. The tandem photovoltaic cell according to claim 73, wherein the graphene film layer forms a recombination contact zone that is configured to collect both positive and negative charges generated from each pair of photoactive subcells.

75. The tandem photovoltaic cell according to claim 73, wherein the graphene film layer forms a common electrode that is configured to collect holes generated from each pair of photoactive subcells, while electrodes associated with each pair of photoactive subcells that are outwardly disposed from the graphene film layer are used as electrical contacts to collect electrons generated from each pair of photoactive subcells.

76. A method of preparing a graphene film layer for disposing between a first photoactive subcell and a second photoactive subcell, comprising: doping the graphene film layer with a conductivity-enhancing dopant.

77. The method according to claim 76, further comprising modifying the graphene film layer with a modifying layer including a PEDOT polymer and a transition metal oxide.

78. The method of transferring a grown graphene film layer onto a targeted material, comprising: a dry transfer process based on a polydimethylsiloxane (PDMS) stamp and applying an etching process.
